(19) United States
(12) Patent Application Publication
(10) Pub. No.: US 2020/0103439 A1
(43) Pub. Date: Apr. 2, 2020

(54) ELECTRONIC COMPONENT HANDLER AND ELECTRONIC COMPONENT TESTER

(71) Applicant: Seiko Epson Corporation, Tokyo (JP)

(72) Inventor: Takahito SANEKATA, Shiojiri (JP)

(21) Appl. No.: 16/583,402

(22) Filed: Sep. 26, 2019

(30) Foreign Application Priority Data
Sep. 27, 2018 (JP) 2018-182646

(51) Int. Cl. G01R 1/04; G01R 13/00; G01R 31/28

(52) U.S. Cl. CPC G01R 1/0433; G01R 31/2851; G01R 13/00

(57) ABSTRACT

An electronic component handler that transports an electronic component to a test unit testing electric characteristics of the electronic component and having a socket member provided with a recess in which the electronic component is placed, includes a reference base having a reference surface in which the socket member is disposed, a measuring unit that measures positions in a normal direction of the reference surface with respect to a plurality of points of the socket member, a display unit, and a control unit that displays position information based on the positions of the plurality of points on the display unit.

The present application is based on, and claims priority from, JP Application Serial Number 2018-182646, filed Sep. 27, 2018, the disclosure of which is hereby incorporated by reference herein in its entirety.

### BACKGROUND

### 1. Technical Field

The present disclosure relates to an electronic component handler and electronic component tester.

### 2. Related Art

In related art, IC examination systems for electrical examinations of IC devices are known (for example, see International Publication 2017/037844). The IC examination system disclosed in International Publication 2017/037844, a socket in which an IC device is placed for examination in the placement state is provided.

The socket may be replaced according to the type of the IC device. Accordingly, some operators who perform replacement work of the sockets may attach the sockets to the IC examination system at tilts. In this case, in the IC examination system disclosed in International Publication 2017/037844, the tilt state of the socket is detected using a non-contact displacement gauge.

International Publication 2017/037844 is an example of the related art.

However, in the IC examination system disclosed in International Publication 2017/037844, no member is provided as a reference for distance measurement, and the non-contact displacement gauge has a problem in accurate detection of the fixing state of the socket.

### SUMMARY

An advantage of some aspects of the present disclosure is to solve the above described problem and the present disclosure can be implemented as the following configurations.

An electronic component handler according to an aspect of the present disclosure is an electronic component handler that transports an electronic component to a test unit testing electric characteristics of the electronic component and having a socket member provided with a recess in which the electronic component is placed. The electronic component handler includes a reference base having a reference surface in which the socket member is disposed, a measuring unit that measures positions in a normal direction of the reference surface with respect to a plurality of points of the socket member, a display unit, and a control unit that displays position information based on the positions of the plurality of points on the display unit.

### BRIEF DESCRIPTION OF THE DRAWINGS

FIG. 1 is a schematic perspective view of an electronic component tester of a first embodiment as seen from a front side.

FIG. 2 is a schematic plan view showing an operation state of the electronic component tester shown in FIG. 1.

FIG. 3 is a schematic front view showing an imaging state within a test region of the electronic component tester shown in FIG. 1.

FIG. 4 is a schematic front view showing an imaging state within the test region of the electronic component tester shown in FIG. 1.

FIG. 5 shows an example of an image captured in the state shown in FIG. 3.

FIG. 6 shows an example of an image captured in the state shown in FIG. 4.

FIG. 7 shows an example of an image captured in a different state from those in FIGS. 5 and 6.

FIG. 8 shows an example of a screen for informing appropriateness of a fixing state of a test unit.

FIG. 9 shows an example of a screen for informing appropriateness of the fixing state of the test unit.

FIG. 10 shows an example of a screen for informing correctness of the test unit itself.

FIG. 11 shows an example of a screen for informing correctness of the test unit itself.

FIG. 12 is a flowchart for explanation of a control operation of a control unit provided in the electronic component tester shown in FIG. 1.

FIG. 13 shows an example of a first entry window for entry of imaging conditions.

FIG. 14 shows an example of a second entry window for entry of imaging conditions.

FIG. 15 shows an example of an image captured within a test region of an electronic component tester of a second embodiment.

FIG. 16 is a block diagram showing an electronic component tester of a third embodiment and around the tester.

FIG. 17 is a block diagram showing an electronic component tester of a fourth embodiment and around the tester.

### DESCRIPTION OF EXEMPLARY EMBODIMENTS

As below, an electronic component handler and electronic component tester of the present disclosure will be explained in detail based on preferred embodiments shown in the accompanying drawings.

### First Embodiment

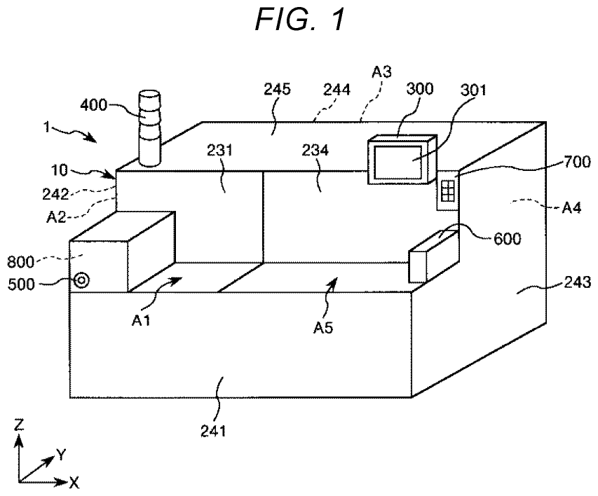

As below, referring to FIGS. 1 to 14, the first embodiment of the electronic component handler and electronic component tester of the present disclosure will be explained. Hereinafter, for convenience of explanation, as shown in FIG. 1, three axes orthogonal to one another are an X-axis (second axis), a Y-axis (first axis), and a Z-axis. Further, an XY-plane containing the X-axis and the Y-axis is horizontal and the Z-axis is vertical. Directions parallel to the X-axis are also referred to as “X-axis directions”, directions parallel to the Y-axis are also referred to as “Y-axis directions”, and directions parallel to the Z-axis are also referred to as “Z-axis directions”. Further, the directions in which arrows point of the respective directions are referred to as “positive” and the opposite directions are referred to as “negative”. In this specification, “horizontal” is not limited to complete horizontal, but includes slight inclinations (e.g. less than ±5° or so) relative to horizontal unless transport of electronic components is hindered. The positive side in the Z-axis direction may be referred to as “upper” or “above” and the negative side in the Z-axis direction may be referred to as “lower” or “below”.

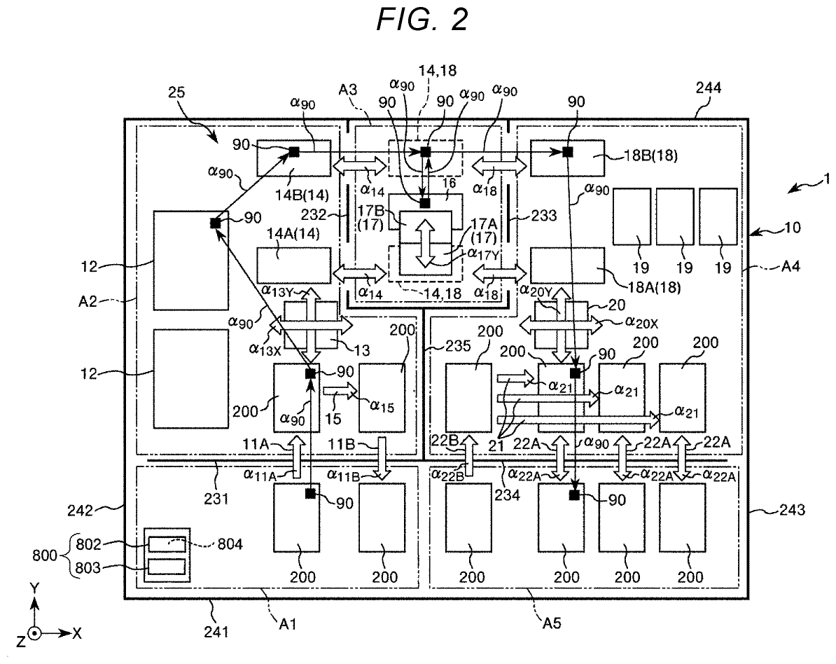

An electronic component handler 10 is a handler having an appearance shown in FIG. 1. Further, as shown in FIG. 2, an electronic component tester 1 includes the electronic component handler 10 and further includes a test unit 16 that tests an electronic component.

As below, the configurations of the respective parts will be explained in detail.

As shown in FIGS. 1 and 2, the electronic component tester 1 including the electronic component handler 10 is an apparatus that transports electronic components such as IC devices e.g. BGA (Ball Grid Array) packages and makes a test and examination (hereinafter, simply referred to as “test”) of electrical characteristics of the electronic components in the transport process. Note that, as below, for convenience of explanation, the case where an IC device is used as the electronic component will be representatively explained with “IC device 90”. In the embodiment, the IC device 90 has a flat plate shape in a rectangular or square shape in the plan view as an example. The plan view shape of the IC device 90 is not limited to the rectangular or square shape, but may be a rounded shape such as a circular shape or elliptical shape, for example.

In addition to the above described package, the IC device includes e.g. “LSI (Large Scale Integration)”, “CMOS (Complementary MOS)”, “CCD (Charge Coupled Device)”, “module IC” formed by packaging of IC devices as a plurality of modules, “crystal device”, “pressure sensor”, “inertial sensor (acceleration sensor)”, “gyro sensor”, “fingerprint sensor”, etc.

The electronic component tester 1 has a tray feed region A1, a device feed region A2, a test region A3, a device collection region A4, and a tray removal region A5, and these regions are partitioned by respective wall parts as will be described later. Further, the IC device 90 sequentially passes the above described respective regions from the tray feed region A1 to the tray removal region A5 in directions of arrows α90, and a test is performed in the test region A3 in the middle. As described above, the electronic component tester 1 includes the electronic component handler 10 having a transporter 25 that transports the IC device 90 to pass the respective regions, the test unit 16 that makes the test within the test region A3, and a control unit 800. Further, the electronic component tester 1 includes a monitor 300, a signal lamp 400, and an operation panel 700.

Note that the electronic component tester 1 is used with a side at which the tray feed region A1 and the tray removal region A5 are provided, i.e., a downside in FIG. 2 as a front side and a side at which the test region A3 is provided, i.e., an upside in FIG. 2 as a back side.

The electronic component tester 1 is used with units called “change kits” arranged and mounted thereon in advance, which are replaced according to the type of the IC device 90. In the embodiment, the change kits include e.g. temperature control units 12, device feed units 14, and device collection units 18, which will be described later. In addition, there are trays 200 prepared by a user, collection trays 19, and the test unit 16 separately from the above described change kits.

The tray feed region A1 is a feed unit to which the trays 200 are fed. The tray 200 is a container in which a plurality of untested IC devices 90 are arranged in a matrix form and placed. The tray feed region A1 may be referred to as “mount region” on which a plurality of the trays 200 can be stacked and mounted. Note that, in the embodiment, a plurality of recesses are arranged in a matrix form in each tray 200. The single IC device 90 may be held and placed in each recess.

The device feed region A2 is a region where the plurality of IC devices 90 on the tray 200 transported from the tray feed region A1 are respectively transported and fed to the test region A3. A tray transport mechanism 11A and a tray transport mechanism 11B that transport the trays 200 one by one in the horizontal directions are provided across the tray feed region A1 and the device feed region A2. The tray transport mechanism 11A is a part of the transporter 25 and may move the tray 200 together with the IC devices 90 placed on the tray 200 toward the positive side in the Y-axis direction, i.e., a direction of an arrow α11A in FIG. 2. Thereby, the IC devices 90 may stably be fed to the device feed region A2. Further, the tray transport mechanism 11B may move the empty tray 200 toward the negative side in the Y-axis direction, i.e., a direction of an arrow α11B in FIG. 2. Thereby, the empty tray 200 may be moved from the device feed region A2 to the tray feed region A1.

In the device feed region A2, the temperature control units 12, a device transport head 13, and a tray transport mechanism 15 are provided. The temperature control unit 12 is called a soak plate in English and, in an example, “ [symbol] [symbol] ” in Chinese. Further, the device feed units 14 that move across the device feed region A2 and the test region A3 are provided.

With the plurality of IC devices 90 placed thereon, the temperature control unit 12 may collectively heat or cool the placed IC devices 90. Thereby, the IC devices 90 before the test in the test unit 16 maybe heated or cooled in advance and controlled to a temperature suitable for the test.

The temperature control units 12 are fixed. Thereby, the IC devices 90 at the temperature control units 12 may be stably temperature-controlled. Further, the temperature control units 12 are grounded.

In the configuration shown in FIG. 2, two temperature control units 12 are arranged in the Y-axis directions and fixed. The IC devices 90 on the tray 200 transported in from the tray feed region A1 by the tray transport mechanism 11A are transported to one of the temperature control units 12.

The device transport head 13 is a holding unit that holds and transports the IC devices 90 and movably supported within the device feed region A2. The device transport head 13 is also a part of the transporter 25, and may serve to transport the IC devices 90 between the tray 200 transported in from the tray feed region A1 and the temperature control unit 12 and transport the IC devices 90 between the temperature control unit 12 and the device feed unit 14, which will be described later. Note that, in FIG. 2, the movement of the device transport head 13 in the X-axis directions is shown by an arrow α13X and the movement of the device transport head 13 in the Y-axis directions is shown by an arrow α13Y.

The device feed unit 14 is called “feed shuttle plate” or simply “feed shuttle” with the temperature-controlled IC devices 90 placed thereon and may transport the IC devices 90 to the vicinity of the test unit 16.

Further, the device feed unit 14 is reciprocably supported in the X-axis directions, i.e., along an arrow α14 between the device feed region A2 and the test region A3. Thereby, the device feed unit 14 may stably transport the IC devices 90 from the device feed region A2 to the vicinity of the test unit 16 in the test region A3, and, after the IC devices 90 are removed by a device transport head 17 in the test region A3, may return to the device feed region A2 again.

In the configuration shown in FIG. 2, two device feed units 14 are arranged in the Y-axis directions, and the device feed unit 14 at the negative side in the Y-axis direction may be referred to as “device feed unit 14A” and the device feed unit 14 at the positive side in the Y-axis direction may be referred to as “device feed unit 14B”. The IC devices 90 on the temperature control unit 12 are transported to the device feed unit 14A or the device feed unit 14B within the device feed region A2. Further, the device feed unit 14 is configured to heat or cool the IC devices 90 placed in the device feed unit 14 like the temperature control unit 12. Thereby, the IC devices 90 temperature-controlled in the temperature control unit 12 may be transported while being maintained in the temperature-controlled state to the vicinity of the test unit 16 of the test region A3. The device feed units 14 are also grounded like the temperature control units 12.

The tray transport mechanism 15 is a mechanism of transporting the empty tray 200 after removal of all IC devices 90 to the positive side in the X-axis direction, i.e., in a direction of an arrow α15 within the device feed region A2. Then, after the transport, the empty tray 200 is returned from the device feed region A2 to the tray feed region A1 by the tray transport mechanism 11B.

The test region A3 is a region where the IC devices 90 are tested. In the test region A3, the test unit 16 that performs tests on the IC devices 90 and the device transport heads 17 are provided.

The device transport heads 17 are a part of the transporter 25 and configured to heat or cool the held IC devices 90 like the temperature control units 12. Thereby, while the IC devices 90 maintained in the temperature-controlled state are held and the temperature-controlled state is maintained, the IC devices 90 may be transported within the test region A3.

The above described device transport heads 17 are reciprocably supported in the Y-axis directions and the Z-axis directions within the test region A3, and form a part of a mechanism called “index arm”. Thereby, the device transport head 17 lifts the IC devices 90 from the device feed unit 14 transported in from the device feed region A2, and transports and places the devices onto the test unit 16.

Note that, in FIG. 2, the reciprocation of the device transport head 17 in the Y-axis directions is shown by an arrow α17Y. Further, the device transport head 17 is reciprocably supported in the Y-axis directions, however, may also be reciprocably supported in the X-axis directions. In the configuration shown in FIG. 2, two device transport heads 17 are arranged in the Y-axis directions, and the device transport head 17 at the negative side in the Y-axis direction may be referred to as “device transport head 17A” and the device transport head 17 at the positive side in the Y-axis direction maybe referred to as “device transport head 17B”. The device transport head 17A may serve to transport the IC devices 90 from the device feed unit 14A to the test unit 16 within the test region A3, and the device transport head 17B may serve to transport the IC devices 90 from the device feed unit 14B to the test unit 16 within the test region A3.

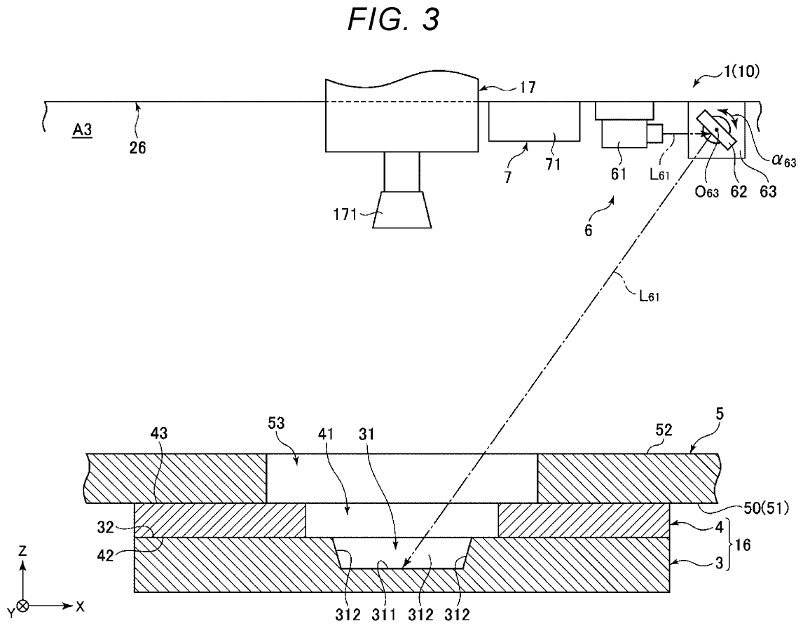

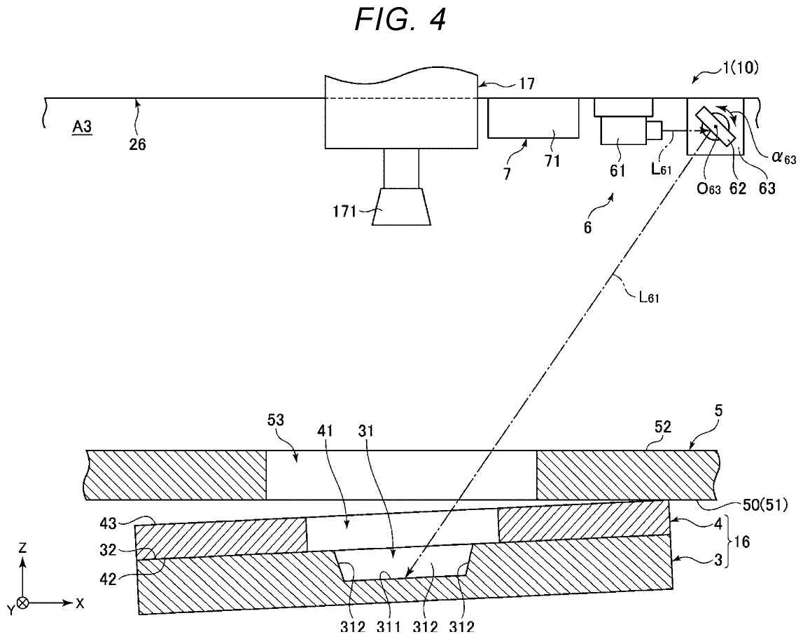

As shown in FIGS. 3 and 4, in the embodiment, the device transport head 17 has a holding unit 171 that holds the IC device 90 by suction. The number of arranged holding units 171 is one in the configuration shown in FIGS. 3 and 4, however, maybe more. When a plurality of holding units 171 are arranged, neither the number of arranged holding units along the X-axis directions nor the number of arranged holding units along the Y-axis directions is limited.

With the IC devices 90 as electronic components thereon, the test unit 16 may test the electric characteristics of the IC devices 90. As shown in FIGS. 3 and 4, the test unit 16 has a socket 3 and a socket base 4 that supports the socket 3 as a socket member.

The socket 3 is formed to open toward the positive side in the Z-axis direction and has a recess 31 in which the single IC device 90 is held and placed. The number of arranged recesses 31 is one in FIGS. 3 and 4, however, maybe more. When a plurality of recesses 31 are arranged, neither the number of arranged recesses along the X-axis directions nor the number of arranged recesses along the Y-axis directions is limited.

A plurality of probe pins (not shown) are provided in a bottom part 311 of the recess 31. The terminal of the IC device 90 and the probe pins are conductively coupled, i.e., in contact, and thereby, the IC device 90 may be tested. The test of the IC device 90 is performed based on a program stored in a test control unit provided in a tester coupled to the test unit 16.

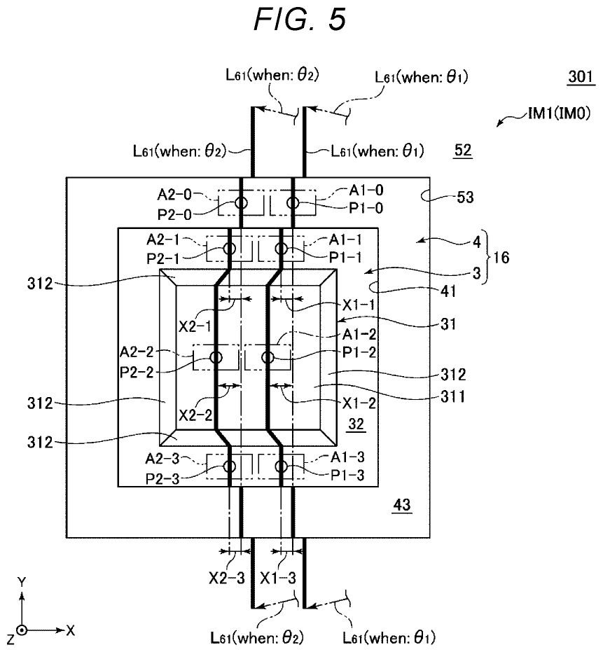

As shown in FIGS. 5 to 7, the recess 31 has four side wall parts 312 inclined relative to the bottom part 311. That is, the inner peripheral part is tapered. Thereby, the IC device 90 may be easily attached to and detached from the recess 31.

The socket 3 may heat or cool the IC device 90 and controls the IC device 90 at a temperature suitable for the test like the temperature control unit 12.

The socket base 4 is a plate-like member having a lower surface 42 in contact with an upper surface 32 of the socket 3 and supporting the socket 3 from a side at which the recess 31 opens, i.e., the positive side in the Z-axis direction. In the socket base 4, a through hole 41 penetrating in the thickness direction is formed. The through hole 41 is provided at the upside of the recess 31 and formed to be larger than the recess 31 in the plan view. Note that the plan view shape of the through hole 41 is square in the configuration shown in FIGS. 5 to 7, however, may be another quadrangular shape such as a rectangular shape or a rounded shape such as a circular shape or elliptical shape, for example.

The device collection region A4 is a region where the plurality of IC devices 90 tested in the test region A3 and finished with tests are collected. In the device collection region A4, the collection trays 19, a device transport head 20, and tray transport mechanisms 21 are provided. Further, the device collection units 18 are also provided across the test region A3 and the device collection region A4. Further, in the device collection region A4, the empty trays 200 are prepared.

With the IC devices 90 finished with the tests in the test unit 16 placed thereon, the device collection unit 18 may transport the IC devices 90 to the device collection region A4, and is referred to as “collection shuttle plate” or simply referred to as “collection shuttle”. The device collection units 18 may also be a part of the transporter 25.

The device collection unit 18 is reciprocably supported in the X-axis directions, i.e., along an arrow α18 between the test region A3 and the device collection region A4. In the configuration shown in FIG. 2, two device collection units 18 are arranged in the Y-axis directions like the device feed units 14, and the device collection unit 18 at the negative side in the Y-axis direction may be referred to as “device collection unit 18A” and the device collection unit 18 at the positive side in the Y-axis direction may be referred to as “device collection unit 18B”. The IC devices 90 on the test unit 16 are transported and placed onto the device collection unit 18A or the device collection unit 18B. Note that the transport of the IC devices 90 from the test unit 16 to the device collection unit 18A is performed by the device transport head 17A and the transport of the IC devices 90 from the test unit 16 to the device collection unit 18B is performed by the device transport head 17B. The device collection units 18 are also grounded like the temperature control units 12 and the device feed units 14.

The collection trays 19 with the IC devices 90 that were tested in the test unit 16 placed thereon are fixed not to move within the device collection region A4. Thereby, even in the device collection region A4 in which various movable parts in the relatively large number including the device transport head 20 are arranged, the tested IC devices 90 are stably placed on the collection trays 19. In the configuration shown in FIG. 2, three collection trays 19 are arranged along the X-axis directions.

Further, three empty trays 200 are arranged along the X-axis directions. The IC devices 90 that were tested in the test unit 16 are also placed on the empty trays 200. The IC devices 90 on the device collection unit 18 moved to the device collection region A4 are transported and placed onto one of the collection tray 19 and the empty tray 200. Thereby, the IC devices 90 are classified with respect to each test result and collected.

The device transport head 20 has a part movably supported in the X-axis directions and the Y-axis directions within the device collection region A4 and further movable in the Z-axis directions. The device transport head 20 is a part of the transporter 25 and may transport the IC devices 90 from the device collection unit 18 to the collection tray 19 or the empty tray 200. Note that, in FIG. 2, the movement of the device transport head 20 in the X-axis directions is shown by an arrow α20X and the movement of the device transport head 20 in the Y-axis directions is shown by an arrow α20Y.

The tray transport mechanism 21 is a mechanism of transporting the empty tray 200 transported from the tray removal region A5 in the X-axis direction, i.e., a direction of arrows α21 within the device collection region A4. Then, after the transport, the empty tray 200 is placed in a position where the IC devices 90 are collected, that is, may be one of the above described three empty trays 200.

The tray removal region A5 is a removing unit in which the tray 200 on which the plurality of tested IC devices 90 are arranged is collected and removed. In the tray removal region A5, many trays 200 may be stacked.

Further, a tray transport mechanism 22A and a tray transport mechanism 22B that transport the trays 200 across the device collection region A4 and the tray removal region A5 one by one in the Y-axis directions are provided. The tray transport mechanism 22A is a moving unit as a part of the transporter 25 that may reciprocate the tray 200 in the Y-axis directions, i.e., directions of an arrow α22A. Thereby, the tested IC devices 90 may be transported from the device collection region A4 to the tray removal region A5. Further, the tray transport mechanism 22B may move the empty tray 200 for collection of the IC devices 90 toward the positive side in the Y-axis direction, i.e., in a direction of an arrow α22B. Thereby, the empty trays 20 may be transported from the tray removal region A5 to the device collection region A4.

The control unit 800 may control operations of the respective parts including e.g. the tray transport mechanism 11A, the tray transport mechanism 11B, the temperature control units 12, the device transport head 13, the device feed units 14, the tray transport mechanism 15, the test unit 16, the device transport heads 17, the device collection units 18, the device transport head 20, the tray transport mechanisms 21, the tray transport mechanism 22A, and the tray transport mechanism 22B. As shown in FIG. 2, for example, in the embodiment, the control unit 800 has at least one processor 802 and at least one memory 803. The processor 802 may read e.g. determination programs, instruction and command programs, etc. as various kinds of information stored in the memory 803, and execute determinations and commands.

Further, the control unit 800 maybe provided inside of the electronic component tester 1 or provided in an external apparatus such as an external computer. The external apparatus may communicate with the electronic component tester 1 via a cable or the like, wirelessly communicate with the tester, or be connected to the electronic component tester 1 via a network such as the Internet, for example.

An operator operating the electronic component tester 1 may set and check operation conditions etc. of the electronic component tester 1 via the monitor 300. The monitor 300 has a display screen 301 formed by e.g. a liquid crystal screen and provided in an upper part at the front side of the electronic component tester 1. As shown in FIG. 1, a mouse stand 600 on which a mouse is placed is provided on the right side of the tray removal region A5 in the drawing. The mouse is used for operation of the screen displayed on the monitor 300.

Further, the operation panel 700 is provided on the lower right of the monitor 300 in FIG. 1. The operation panel 700 commands the electronic component tester 1 to perform a desired operation separately from the monitor 300.

The signal lamp 400 may inform the operation state of the electronic component tester 1 etc. by combinations of colors of light to emit. The signal lamp 400 is provided in an upper part of the electronic component tester 1. Note that a speaker 500 is provided inside of the electronic component tester 1, and the speaker 500 may also inform the operation state of the electronic component tester 1 etc.

The electronic component tester 1 is partitioned between the tray feed region A1 and the device feed region A2 by a first partition wall 231, partitioned between the device feed region A2 and the test region A3 by a second partition wall 232, partitioned between the test region A3 and the device collection region A4 by a third partition wall 233, and partitioned between the device collection region A4 and the tray removal region A5 by a fourth partition wall 234. Further, the tester is partitioned between the device feed region A2 and the device collection region A4 by a fourth partition wall 235.

The outermost exterior of the electronic component tester 1 is covered by covers and the covers include e.g. a front cover 241, a side cover 242, a side cover 243, a rear cover 244, and a top cover 245.

As shown in FIGS. 3 and 4, the electronic component tester 1 has a reference base 5 in a plate-like shape provided parallel to the XY-plane. The reference base 5 may support and fix the test unit 16 within the test region A3. Note that the test unit 16 is detachably fixed to the reference base 5 and the fixing method is not particularly limited to, but includes a method of fastening by screws or the like, for example.

The socket 3 is fixed to the reference base 5 at a lower surface 51 side via the socket base 4. The lower surface 51 serves as a reference surface 50 as a fixation reference position in the Z-axis directions for fixation of the test unit 16. A plurality of the test units 16 are prepared with respect to each type of the IC device 90, and every test unit 16 is fixed with an upper surface 43 of the socket base 4 in contact with the reference surface 50.

Further, the reference base 5 has an opening part 53 formed to penetrate in the thickness direction, i.e., open in an upper surface 52 and the lower surface 51. The opening part 53 is provided at the upside of the through hole 41 of the socket base 4 and is formed to be larger than the through hole 41 in the plan view. Thereby, the recess 31 of the socket 3 faces and communicates with the opening part 53 via the through hole 41. The IC device 90 may easily pass through the opening part 53 when the IC device 90 is placed in the recess 31 or lifted from the recess 31 by the device transport head 17. Note that the plan view shape of the opening part 53 is square in the configuration shown in FIGS. 5 to 7, however, may be another quadrangular shape such as a rectangular shape or a rounded shape such as a circular shape or elliptical shape, for example.

As described above, in the electronic component tester 1, the test unit 16 is replaced for each type of the IC devices 90. The operator operating the electronic component tester 1 may replace and fix the test unit 16 to the reference base 5 as appropriate. At this time, for example, the test unit 16 is in the state shown in FIG. 3 or the state shown in FIG. 4.

The state shown in FIG. 3 is a state in which the test unit 16 is accurately fixed to the reference base 5. In this state, the device transport head 17 may accurately and smoothly place the IC device 90 in the recess 31 of the socket 3 and may accurately and smoothly lift the placed IC device 90 from the recess 31. An example of an image captured in the state shown in FIG. 3 is an image IM1 shown in FIG. 5.

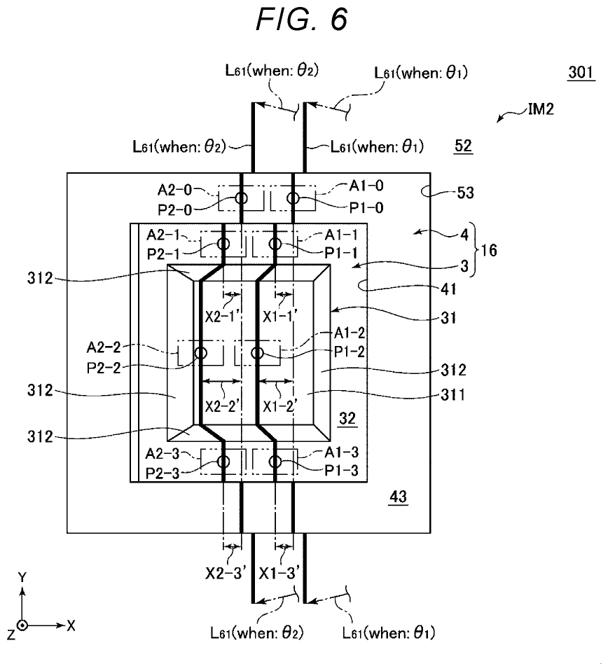

On the other hand, the state shown in FIG. 4 is inaccurate fixation in which the test unit 16 is inclined and fixed relative to the reference base 5. In this state, it may be impossible for the device transport head 17 to accurately place the IC device 90 in the recess 31 of the socket 3. Or, even when the IC device 90 is placed in the recess 31, it may be difficult for the device transport head 17 to lift the IC device 90 from the recess 31. An example of an image captured in the state shown in FIG. 4 is an image IM2 shown in FIG. 6.

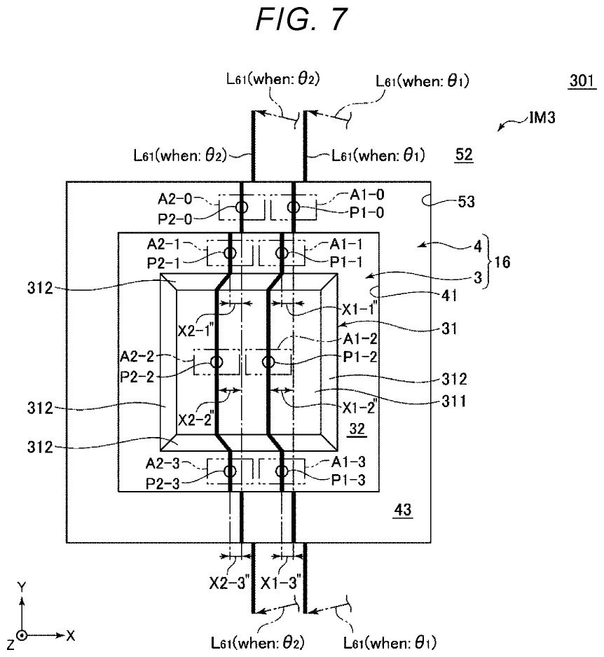

Or, when replacing the test unit 16, the operator may accurately fix the test unit 16 to the reference base 5, but the test unit 16 may be an incorrect test unit 16 unsuitable for the IC device 90. Also, in this case, as is the case shown in FIG. 4, placement of the IC device 90 in the recess 31 and transport of the IC device 90 from the recess 31 may be difficult. An example of an image captured in the state with the incorrect test unit 16 fixed to the reference base 5 is an image IM3 shown in FIG. 7. In the image IM3, the recess 31 in the plan view has a rectangular shape different from the square recess 31 in the image IM1.

Accordingly, the electronic component tester 1 is configured to solve the above described concerns by determinations of appropriateness of the fixing state of the test unit 16 and correctness of the test unit 16 itself. As below, the configuration and action will be explained.

As shown in FIGS. 3 and 4, the electronic component tester 1 includes a light radiation unit 6 that radiates a laser beam L61 toward the opening part 53 of the reference base 5, and an imaging unit 7 that captures an image containing the opening part 53 radiated by the laser beam L61 and around. The images captured by the imaging unit 7 include e.g. the image IM1, the image IM2, and the image IM3. Further, a radiation timing of the laser beam L61 by the light radiation unit 6, an imaging timing by the imaging unit 7, etc. are controlled by the control unit 800.

The light radiation unit 6 has a laser beam radiation part 61 that radiates the laser beam L61 as an example of light, a reflection part 62 that reflects the laser beam L61, and a pivot supporting part 63 that pivotably supports the reflection part 62. Thereby, the laser beam L61 has excellent directionality and may stably travels toward the opening part 53 as a radiation target position of the laser beam L61.

The laser beam radiation part 61 is provided above the reference base 5 and fixed relative to the reference base 5. The fixation location of the laser beam radiation part 61 is not particularly limited, but preferably e.g. a frame 26 provided in parallel to the XY-plane within the test region A3 or the like. The laser beam radiation part 61 is fixed within the test region A3, and thereby, may stably radiate the laser beam L61 and contributes to accurate detection of appropriateness of the fixing state of the test unit 16 and correctness of the test unit 16 itself.

The laser beam radiation part 61 may radiate the laser beam L61 toward the positive side in the X-axis direction. Note that the laser beam L61 is not particularly limited, but preferably e.g. a semiconductor laser.

The light radiation unit 6 is configured to radiate the laser beam L61 using the laser beam radiation part 61, however, may be configured to radiate e.g. radiation light such as infrared light.

The reflection part 62 is provided at the positive side in the X-axis direction of the laser beam radiation part 61. The reflection part 62 includes a mirror and may reflect the laser beam L61. Thereby, the laser beam L61 is radiated to the opening part 53 of the reference base 5 as a slit light from diagonally right above along the Y-axis directions in FIGS. 3 and 4. Thereby, in a portion radiated by the laser beam L61 inside of the opening part 53, for example, linear radiation shapes shown by thick lines in FIGS. 5 to 7 are obtained.

The reflection part 62 is pivotably supported in directions of an arrow α63 about a pivot axis O63 parallel to the Y-axis directions via the pivot supporting part 63. The configuration of the pivot supporting part 63 is not particularly limited, but may be e.g. a configuration having a motor and a reducer coupled to the motor. Note that it is preferable that the pivot supporting part 63 is fixed to the frame 26 within the test region A3 like the laser beam radiation part 61.

As described above, the light radiation unit 6 has the pivot supporting part 63 supporting the reflection part 62 so that the reflection part 62 may pivot in the directions of the arrow α63. Thereby, when the reflection part 62 is rotated, the radiation direction of the laser beam L61 to the opening part 53 of the reference base 5 changes by the amount of rotation, and thereby, the radiation position of the laser beam L61 inside of the opening part 53 may be changed along the X-axis directions. In FIGS. 5 to 7, the radiation position of the laser beam L61 is respectively changed to two locations.

The light radiation unit 6 is configured to pivot the reflection part 62 including the mirror having a relatively light weight of the components forming the light radiation unit 6. Thereby, the reflection part 62 may be stably and quickly pivoted, and thus, the laser beam L61 may be stably and accurately directed toward the opening part 53 in cooperation with the high directionality of the laser beam L61.

Note that the number of disposed light radiation units 6 is one in the embodiment, however, may be more.

The imaging unit 7 is provided above the reference base 5 at the negative side of the X-axis direction of the laser beam radiation part 61 and fixed relative to the reference base 5. The fixation location of the imaging unit 7 is not particularly limited, but preferably the frame 26 within the test region A3 like the laser beam radiation part 61, for example.

The imaging unit 7 in an imaging direction downward may capture the image containing the opening part 53 radiated by the laser beam L61 and around. Note that the imaging unit 7 is not particularly limited, but e.g. a camera 71 such as a CCD camera may be used.

Further, the number of disposed imaging units 7 is one in the embodiment, however, may be more.

Furthermore, it is preferable that the imaging unit 7 captures the image after the pivot of the reflection part 62 is stopped. Thereby, image blurring of the laser beam L61 inside of the opening part 53 may be prevented, and thus, an image with high accuracy in which the laser beam L61 is clearly taken may be acquired.

In the electronic component tester 1, for determinations of appropriateness of the fixing state of the test unit 16 and correctness of the test unit 16 itself, a plurality of points are set inside of the opening part 53 on the display screen 301 of the monitor 300. The setting is made by a setting part 804 of the control unit 800. In the embodiment, a part of a circuit provided inside of the processor 802 functions as the setting part 804.

In the configuration shown in FIGS. 5 to 7, the points set by the setting part 804 include a point P1-0, a point P1-1, a point P1-2, a point P1-3, a point P2-0, a point P2-1, a point P2-2, and a point P2-3. Further, the control unit 800 also has a function as a measuring unit that measures positions in the normal direction of the reference surface 50 with respect to these points.

The point P1-0 to point P1-3 are set along one direction of planar directions of the reference surface 50 parallel to the XY-plane, particularly, a first line parallel to the Y-axis directions (first axis) and measured. The point P1-0 is a reference point among the point P1-0 to point P1-3, and the point P1-1, the point P1-2, and the P1-3 are sequentially set toward the negative side in the Y-axis direction with reference to the P1-0.

The point P2-0 to point P2-3 are set at the negative side in the X-axis direction of the point P1-0 to point P1-3 and set along the Y-axis directions like the point P1-0 to point P1-3 and measured subsequently to the point P1-0 to point P1-3. The point P2-0 is a reference point among the point P2-0 to point P2-3, and the point P2-1, the point P2-2, and the P2-3 are sequentially set toward the negative side in the Y-axis direction with reference to the P2-0. Further, the point P2-0 is set at the negative side in the X-axis directions (second axis) of the point P1-0 with reference to the point P1-0.

In the configuration shown in FIGS. 5 to 7, both the point P1-0 and the point P2-0 are points on the upper surface 43 of the socket base 4. Further, when being in contact with the reference surface 50 of the reference base 5 as shown in FIG. 3, the upper surface 43 is in the same position as the reference surface 50 with respect to the Z-axis directions.

In the configuration shown in FIGS. 5 and 6, the point P1-1 and the point P2-1 are points on the upper surface 32 of the socket 3, and, in the configuration shown in FIG. 7, points on the wall part 312 located at the positive side in the Y-axis directions of the recess 31 of the socket 3.

In the configuration shown in FIGS. 5 to 7, both the point P1-2 and the point P2-2 are points on the bottom part 311 of the recess 31 of the socket 3.

In the configuration shown in FIGS. 5 and 6, the point P1-3 and the point P2-3 are points on the upper surface 32 of the socket 3, and, in the configuration shown in FIG. 7, points on the wall part 312 located at the negative side in the Y-axis directions of the recess 31 of the socket 3.

The setting part 804 may also set an area A1-0 containing the point P1-0. Note that, as shown in FIGS. 5 to 7, “area A1-0” refers to a region containing at least the point P1-0 and a margin around the point and may be any shape such as a rectangular shape, square shape, circular shape, or elliptical shape. In the illustrated configuration, the region has a rectangular shape. Note that the area A1-0 does not necessarily contain the margin. The area A1-0 is set by the setting part 804.

Similarly, the setting part 804 may also set an area A1-1 containing the point P1-1, an area A1-2 containing the point P1-2, an area A1-3 containing the point P1-3, an area A2-0 containing the point P2-0, an area A2-1 containing the point P2-1, an area A2-2 containing the point P2-2, and an area A2-3 containing the point P2-3.

As described above, the setting part 804 may set the plurality of points along one direction of the planar directions of the reference surface 50 parallel to the XY-plane, particularly, the Y-axis directions, and may set the plurality of points along another direction crossing the one direction of the reference surface 50 directions parallel to the XY-plane, particularly, the X-axis directions. In other words, the setting part 804 may set the plurality of points in a matrix form along both the X-axis directions and the Y-axis directions. Thereby, as will be described later, regarding the respective points, position information on the positions in the normal direction of the reference surface 50, i.e., in the Z-axis directions may be displayed on the display screen 301 of the monitor 300.

Note that the number of set points and set positions of the points set by the setting part 804 are not limited to the configurations shown in FIGS. 5 to 7.

In the light radiation unit 6, when the laser beam L61 is radiated toward the opening part 53 with the reflection part 62 pivoted and stopped at a first angle el, the radiation shape of the laser beam L61 inside of the opening part 53 is a shape passing through all of the area A1-0 containing the point P1-0, the area A1-1 containing the point P1-1, the area A1-2 containing the point P1-2, and the area A1-3 containing the point P1-3. Thereby, regarding the point P1-0 to the point P1-3, the position information on the positions in the Z-axis directions, i.e., the height directions may quickly be detected.

Further, in the light radiation unit 6, when the laser beam L61 is radiated toward the opening part 53 with the reflection part 62 pivoted and stopped at a second angle θ2 different from the first angle θ1, the radiation shape of the laser beam L61 inside of the opening part 53 is a shape passing through all of the area A2-0 containing the point P2-0, the area A2-1 containing the point P2-1, the area A2-2 containing the point P2-2, and the area A2-3 containing the point P2-3. Thereby, regarding the point P2-0 to the point P2-3, the position information on the positions in the Z-axis directions, i.e., the height directions may be quickly detected.

In the control unit 800, the processor 802 may display the position information on the positions in the Z-axis directions regarding the point P1-0 to the point P1-3 and the point P2-0 to the point P2-3 based on the image IM1, the image IM2, and the image IM3 on the display screen 301 of the monitor 300.

Then, the control unit 800 may obtain the position information of the laser beam L61 passing through the area A1-0 to the area A1-3 based on differences in number of pixels in the X-axis directions of the laser beams L61 within the respective areas in the image IM1, the image IM2, and the image IM3. Further, the control unit 800 may obtain the position information of the laser beam L61 passing through the area A2-0 to the area A2-3 based on differences in number of pixels in the X-axis directions of the laser beams L61 within the respective areas in the image IM1, the image IM2, and the image IM3. According to the configuration, the respective position information may be accurately detected.

For example, in the image IM1 shown in FIG. 5, the laser beam L61 within the area A1-1 is shifted toward the negative side in the X-axis direction by a distance X1-1 relative to the laser beam L61 within the area A1-0 containing the point P1-0 as the reference point, and the number of pixels corresponding to the distance X1-1 is obtained. The laser beam L61 within the area A1-2 is shifted toward the negative side in the X-axis direction by a distance X1-2 relative to the laser beam L61 within the area A1-0, and the number of pixels corresponding to the distance X1-2 is obtained. The laser beam L61 within the area A1-3 is shifted toward the negative side in the X-axis direction by a distance X1-3 relative to the laser beam L61 within the area A1-0, and the number of pixels corresponding to the distance X1-3 is obtained.

Further, in the image IM1, the laser beam L61 within the area A2-1 is shifted toward the negative side in the X-axis direction by a distance X2-1 relative to the laser beam L61 within the area A2-0 containing the point P2-0 as the reference point, and the number of pixels corresponding to the distance X2-1 is obtained. The laser beam L61 within the area A2-2 is shifted toward the negative side in the X-axis direction by a distance X2-2 relative to the laser beam L61 within the area A2-0, and the number of pixels corresponding to the distance X2-2 is obtained. The laser beam L61 within the area A2-3 is shifted toward the negative side in the X-axis direction by a distance X2-3 relative to the laser beam L61 within the area A2-0, and the number of pixels corresponding to the distance X2-3 is obtained.

In the electronic component tester 1, an image IM0 as the same image data as the image IM1 is stored in the memory 803 in advance as mother data for determinations of appropriateness of the fixing state of the test unit 16 and correctness of the test unit 16 itself.

In the image IM2 shown in FIG. 6, the laser beam L61 within the area A1-1 is shifted toward the negative side in the X-axis direction by a distance X1-1′ relative to the laser beam L61 within the area A1-0, and the number of pixels corresponding to the distance X1-1′ is obtained. The laser beam L61 within the area A1-2 is shifted toward the negative side in the X-axis direction by a distance X1-2′ relative to the laser beam L61 within the area A1-0, and the number of pixels corresponding to the distance X1-2′ is obtained. The laser beam L61 within the area A1-3 is shifted toward the negative side in the X-axis direction by a distance X1-3′ relative to the laser beam L61 within the area A1-0, and the number of pixels corresponding to the distance X1-3′ is obtained.

Further, in the image IM2, the laser beam L61 within the area A2-1 is shifted toward the negative side in the X-axis direction by a distance X2-1′ relative to the laser beam L61 within the area A2-0, and the number of pixels corresponding to the distance X2-1′ is obtained. The laser beam L61 within the area A2-2 is shifted toward the negative side in the X-axis direction by a distance X2-2′ relative to the laser beam L61 within the area A2-0, and the number of pixels corresponding to the distance X2-2′ is obtained. The laser beam L61 within the area A2-3 is shifted toward the negative side in the X-axis direction by a distance X2-3′ relative to the laser beam L61 within the area A2-0, and the number of pixels corresponding to the distance X2-3′ is obtained.

In the image IM3 shown in FIG. 7, the laser beam L61 within the area A1-1 is shifted toward the negative side in the X-axis direction by a distance X1-1″ relative to the laser beam L61 within the area A1-0, and the number of pixels corresponding to the distance X1-1″ is obtained. The laser beam L61 within the area A1-2 is shifted toward the negative side in the X-axis direction by a distance X1-2″ relative to the laser beam L61 within the area A1-0, and the number of pixels corresponding to the distance X1-2″ is obtained. The laser beam L61 within the area A1-3 is shifted toward the negative side in the X-axis direction by a distance X1-3″ relative to the laser beam L61 within the area A1-0, and the number of pixels corresponding to the distance X1-3″ is obtained.

Further, in the image IM3, the laser beam L61 within the area A2-1 is shifted toward the negative side in the X-axis direction by a distance X2-1″ relative to the laser beam L61 within the area A2-0, and the number of pixels corresponding to the distance X2-1″ is obtained. The laser beam L61 within the area A2-2 is shifted toward the negative side in the X-axis direction by a distance X2-2″ relative to the laser beam L61 within the area A2-0, and the number of pixels corresponding to the distance X2-2″ is obtained. The laser beam L61 within the area A2-3 is shifted toward the negative side in the X-axis direction by a distance X2-3″ relative to the laser beam L61 within the area A2-0, and the number of pixels corresponding to the distance X2-3″ is obtained.

In the cases where the actually captured image is e.g. one of the image IM1, the image IM2, and the image IM3, the determinations of appropriateness of the fixing state of the test unit 16 and correctness of the test unit 16 itself are made in the following manners.

### Case 1

In the case where the actually captured image is the image IM1

First, a magnitude relationship between the distances X1-1, a magnitude relationship between the distances X1-2, a magnitude relationship between the distances X1-3, a magnitude relationship between the distances X2-1, a magnitude relationship between the distances X2-2, and a magnitude relationship between the distances X2-3 are detected between the image IMO as the mother data and the image IM1.

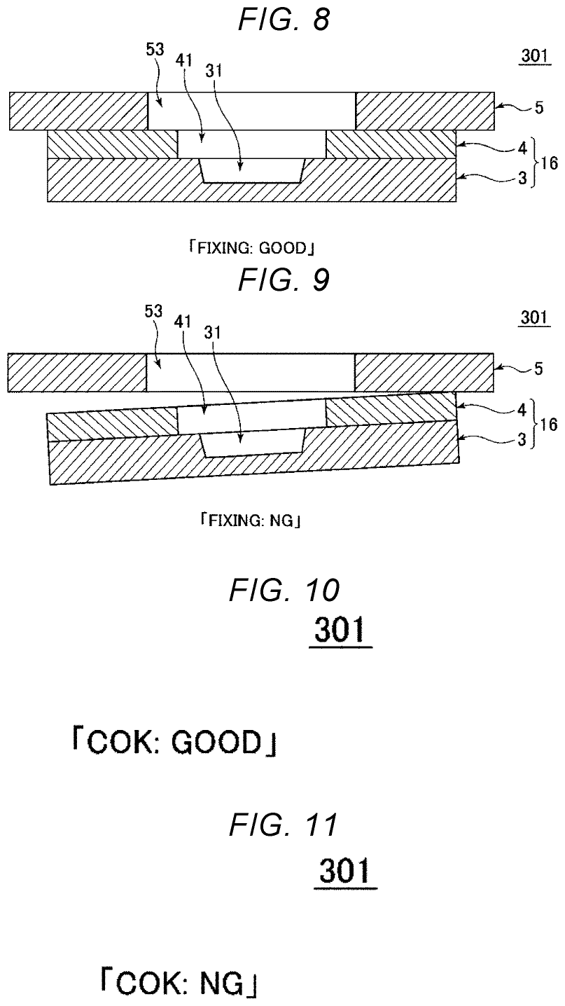

Then, in the detection result, when determinations that the distances X1-1 are the same in magnitude, the distances X1-2 are the same in magnitude, the distances X1-3 are the same in magnitude, the distances X2-1 are the same in magnitude, the distances X2-2 are the same in magnitude, and the distances X2-3 are the same in magnitude are made, the determination results that the fixing state of the test unit 16 is good and the test unit 16 itself is correct are displayed on the monitor 300. In this regard, the images displayed on the monitor 300 include e.g. images shown in FIGS. 8 and 10. FIG. 8 shows “the fixing state of the test unit 16 is good” and FIG. 10 shows “the test unit 16 itself is correct”.

### Case 2

In the case where the actually captured image is the image IM2

First, a magnitude relationship between the distance X1-1 and the distance X1-1′, a magnitude relationship between the distance X1-2 and the distance X1-2′, a magnitude relationship between the distance X1-3 and the distance X1-3′, a magnitude relationship between the distance X2-1 and the distance X2-1′, a magnitude relationship between the distance X2-2 and the distance X2-2′, and a magnitude relationship between the distance X2-3 and the distance X2-3′ are detected between the image IM0 as the mother data and the image IM2.

Then, in the detection result, when determinations that the distance X1-1<the distance X1-1′, the distance X1-2<the distance X1-2′, the distance X1-3<the distance X1-3′, the distance X2-1<the distance X2-1′, the distance X2-2<the distance X2-2′, and the distance X2-3<the distance X2-3′ are made, the determination results that the test unit 16 itself is correct, but the fixing state of the test unit 16 is not good are displayed on the monitor 300. In this regard, the images displayed on the monitor 300 include e.g. images shown in FIGS. 9 and 10. FIG. 9 shows “the fixing state of the test unit 16 is not good”.

### Case 3

In the case where the actually captured image is the image IM3

First, a magnitude relationship between the distance X1-1 and the distance X1-1″, a magnitude relationship between the distance X1-2 and the distance X1-2″, a magnitude relationship between the distance X1-3 and the distance X1-3″, a magnitude relationship between the distance X2-1 and the distance X2-1″, a magnitude relationship between the distance X2-2 and the distance X2-2″, and a magnitude relationship between the distance X2-3 and the distance X2-3″ are detected between the image IMO as the mother data and the image IM3.

Then, in the detection result, when determinations that the distance X1-1<the distance X1-1″, the distance X1-2=the distance X1-2″, the distance X1-3<the distance X1-3″, the distance X2-1<the distance X2-1″, the distance X2-2=the distance X2-2″, and the distance X2-3<the distance X2-3″ are made, the determination results that the fixing state of the test unit 16 is good, but the test unit 16 itself is not correct are displayed on the monitor 300. In this regard, the images displayed on the monitor 300 include e.g. images shown in FIGS. 8 and 11. FIG. 11 shows “the test unit 16 itself is not correct”.

As described above, the control unit 800 may determine both whether or not the fixing state of the test unit 16 is good and whether or not the test unit 16 itself is correct based on the position information of the laser beams L61 within the respective areas. Thereby, whether or not the fixing state of the test unit 16 is good and whether or not the disposed test unit 16 is the test unit 16 suitable for the use may quickly and accurately be determined. When the fixing state of the test unit 16 is good and the test unit 16 itself is correct, the tester may transition to the test of the IC device 90. Or, when the fixing state of the test unit 16 is not good, the fixing state of the test unit 16 is corrected, and then, the tester may transition to the test of the IC device 90. Or, when the test unit 16 itself is not correct, the test unit 16 is replaced by the correct one, and the tester may transition to the test of the IC device 90.

Note that the control unit 800 is configured to determine both whether or not the fixing state of the test unit 16 is good and whether or not the test unit 16 itself is correct, however, may be configured to make one of the determinations.

The position information on the point P1-0 to the point P1-3 and the point P2-0 to the point P2-3 are displayed, however, not limited to that. Position information on at least two points of the point P1-0 to the point P1-3 may be displayed, and position information on at least two points of the point P2-0 to the point P2-3 may be displayed.

As the state in which the fixing state of the test unit 16 is not good, FIG. 4 shows the state in which the test unit 16 is inclined relative to the leftward and rightward directions as an example, however, the state is not limited to that. For example, the state may be a state in which the test unit 16 is inclined from the near side toward the far side of the paper surface of FIG. 4.

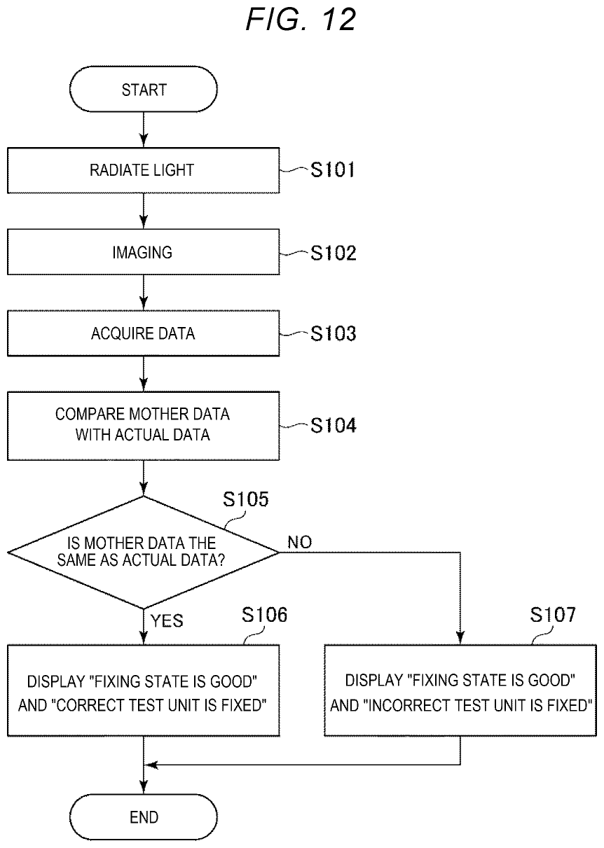

Next, the control operation by the control unit 800 will be explained according to a flowchart shown in FIG. 12.

First, the light radiation unit 6 is activated, the laser beam L61 is radiated toward the opening part 53 of the reference base 5, and the radiation state is maintained (step S101).

Then, the imaging unit 7 is activated and the image inside of the opening part 53 is captured (step S102).

Then, as described above, the positions of the laser beams L61 within the respective areas in the image captured at step S102 are detected and acquired (step S103), and the position relationships among the laser beams L61 within the respective areas are compared between the mother data and the image captured at step S102 (step S104).

Then, as described above, whether or not the position relationships among the laser beams L61 within the respective areas are the same is determined (step S105), when the relationships are the same, the determination results that the fixing state of the test unit 16 is good and the test unit 16 itself is correct are displayed on the monitor 300 (step S106). On the other hand, as a result of the determination at step S105, when the relationships are different, the determination results that the fixing state of the test unit 16 is not good or the test unit 16 itself is not correct, or both are not are displayed on the monitor 300 (step S107).

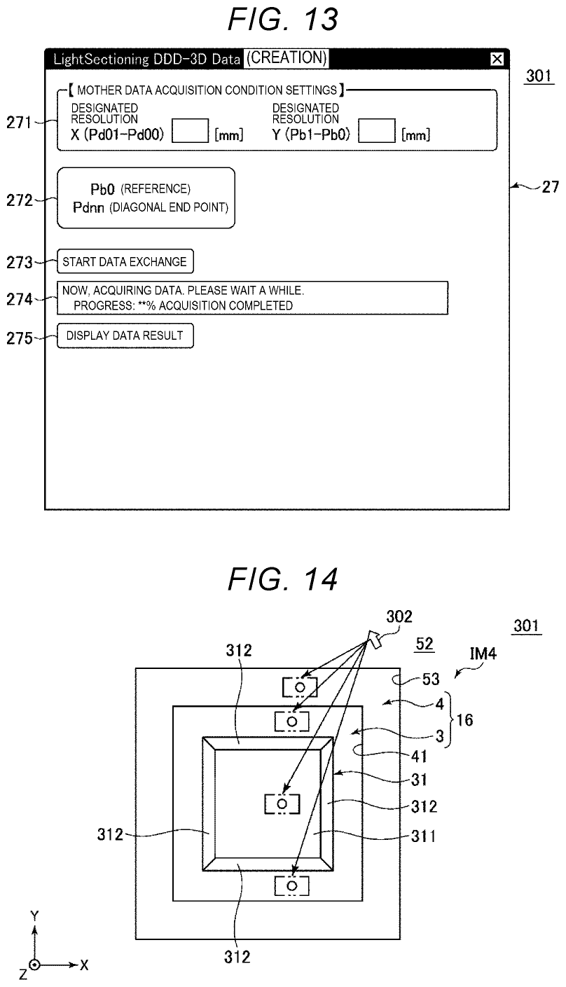

Next, a setting window for determinations as to whether or not the fixing state of the test unit 16 is good and whether or not the test unit 16 itself is correct will be explained with reference to FIGS. 13 and 14.

As shown in FIG. 13, a setting form 27 as a setting window is displayed on the display screen 301. In the setting form 27, a first entry part 271 for setting conditions for acquirement of mother data, a second entry part 272 for entry of points set by the setting part 804, a start command part 273 for starting acquisition of position data of the points entered in the second entry part 272, a first message part 274 for informing an acquisition state of the position data, and a second message part 275 for informing an acquisition result of the position data.

When the second entry part 272 is operated, an image IM4 shown in FIG. 14 is displayed on the display screen 301. The image IM4 shows inside of the opening part 53 of the reference base 5. The operator may move a pointer 302 in the display screen 301 in directions of arrows in FIG. 14 by operating a mouse (not shown). Then, the operator appropriately enters and settles the points set by the setting part 804 by clicking the mouse at the movement destination of the pointer 302.

As described above, the electronic component handler 10 is the apparatus including the tray 200 as the container on which the IC devices 90 as the electronic components are placed, the socket 3 having the recess 31 in which the IC device 90 is placed, and the socket base 4 having the plate-like shape supporting the socket 3 from the side at which the recess 31 opens, and transporting the IC devices 90 between the test unit 16 that tests the electric characteristics of the IC devices 90 and the apparatus. The electronic component handler 10 includes the reference base 5 having the reference surface 50 to which the socket 3 is fixed via the socket base 4 as a fixation reference position of the test unit 16 and the opening part 53 through which the IC device 90 passes when the IC device 90 is placed in the recess 31, the light radiation unit 6 fixed relative to the reference base 5 and radiating the laser beam L61 (light) to the opening part 53, the imaging unit 7 fixed relative to the reference base 5 and capturing e.g. the image IM1 of the opening part 53 radiated by the laser beam L61, and the control part 800 having the setting part 804 that sets e.g. the point P1-0 to point P1-3 inside of the opening part 53 and displaying the position information on the positions in the normal direction of the reference surface 50 with respect to at least two points of the point P1-0 to point P1-3 based on e.g. the image IM1 on the monitor 300 as a display unit.

Or, the electronic component handler 10 includes the reference base 5 having the reference surface 50 to which the socket 3 is fixed via the socket base 4 as the fixation reference position of the test unit 16 and the opening part 53 through which the IC device 90 passes when the IC device 90 is placed in the recess 31, the light radiation unit 6 fixed relative to the reference base 5 and radiating the laser beam L61 (light) to the opening part 53, the camera 71 fixed relative to the reference base 5 and capturing e.g. the image IM1 of the opening part 53 radiated by the laser beam L61, and the processor 802. The processor 802 has the setting part 804 that sets e.g. the point P1-0 to point P1-3 inside of the opening part 53 and may display the position information on the positions in the normal direction of the reference surface 50 with respect to at least two points of the point P1-0 to point P1-3 based on e.g. the image IM1 on the monitor 300 as the display unit.

Note that, as shown in the related art, when the non-contact displacement gauge is provided in a robot arm that holds and transports the IC device and scans the socket with a beam with movement of the robot arm, it may be impossible to accurately detect the fixing state of the socket depending on the movement speed of the robot arm. Or, for example, when the position of the non-contact displacement gauge at the measurement is changed or the position of the non-contact displacement gauge is shifted and fixed, the distance between the non-contact displacement gauge and the socket changes, and it may be impossible to accurately detect the fixing state of the socket.

On the other hand, according to the present disclosure, the reference surface 50 of the reference base 5 is used as the reference for measurement of the distance and the position of the socket 3 relative to the reference surface 50 is measured, and thus, as described above, whether or not the fixing state of the test unit 16 is good and whether or not the test unit 16 itself is correct may be accurately determined.

Further, the electronic component tester 1 includes the electronic component handler 10, and further includes the test unit 16 that tests the IC devices 90. That is, the electronic component tester 1 is the apparatus that tests the IC devices 90 transported to the tray 200 on which the IC devices 90 are placed, and includes the test unit 16 including the socket 3 having the recess 31 in which the IC device 90 is placed and the socket base 4 having the plate-like shape supporting the socket 3 from the side at which the recess 31 opens and testing the electric characteristics of the IC devices 90, the reference base 5 having the reference surface 50 to which the socket 3 is fixed via the socket base 4 as the fixation reference position of the test unit 16 and the opening part 53 through which the IC device 90 passes when the IC device 90 is placed in the recess 31, the light radiation unit 6 fixed relative to the reference base 5 and radiating the laser beam L61 (light) to the opening part 53, the imaging unit 7 fixed relative to the reference base 5 and capturing e.g. the image IM1 of the opening part 53 radiated by the laser beam L61, and the control part 800 having the setting part 804 that sets e.g. the point P1-0 to point P1-3 inside of the opening part 53 and displaying the position information on the positions in the normal direction of the reference surface 50 with respect to at least two points of the point P1-0 to point P1-3 based on e.g. the image IM1 on the monitor 300 as the display unit.

Thereby, the electronic component tester 1 having the advantages of the above described electronic component handler 10 is obtained. Further, the IC devices 90 may be transported up to the test unit 16, and thus, the tests on the IC devices 90 may be performed in the test unit 16. Further, the IC devices 90 after the tests may be transported from the test unit 16.

Note that, instead of using the light radiation unit 6 that radiates the laser beam L61 and the imaging unit 7, a spot-type laser displacement sensor, fiber sensor with small spot lens, or ultrasonic sensor may be used. In any case, generally, a sensor that may narrow down to a minute point to set a plurality of points on the small socket 3 for detecting distances from the points maybe employed. In the case of using the sensor, the distances may be directly measured, not the numbers of pixels.

### Second Embodiment

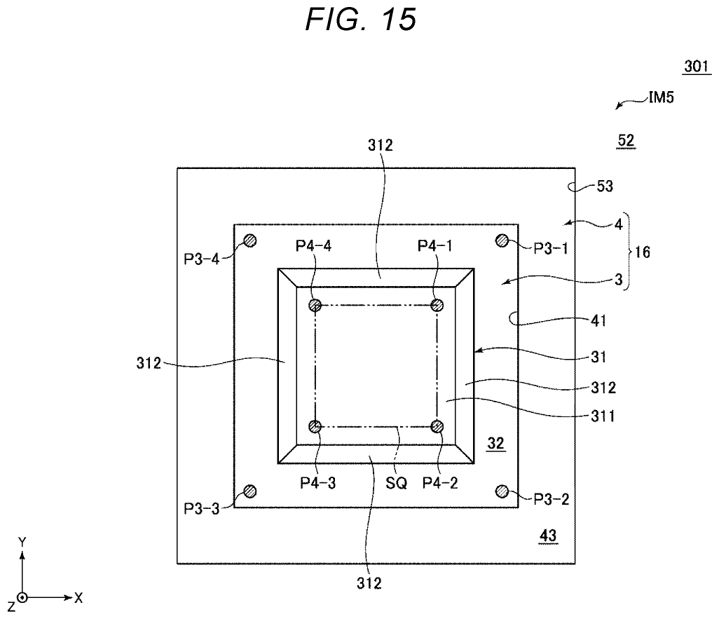

As below, the second embodiment of the electronic component handler and the electronic component tester of the present disclosure will be explained with reference to FIG. 15. The explanation will be made with a focus on the differences from the above described embodiment and the explanation of the same items will be omitted.

This embodiment is the same as the above described first embodiment except that the locations of the points set by the setting part are different.

As shown in FIG. 15, an image IM5 is displayed on the display screen 301. The image IM5 contains a plurality of points set by the setting part 804. These points include a point P3-1, a point P3-2, a point P3-3, a point P3-4, a point P4-1, a point P4-2, a point P4-3, and a point P4-4.

The point P3-1 to point P3-4 are set in four corners of the upper surface 32 of the socket 3 exposed from the through hole 41 of the socket base 4.

The point P4-1 to point P4-4 are set in four corners of the bottom part 311 of the recess 31 of the socket 3. A square SQ formed by connection of the point P4-1 to point P4-4 is smaller in size than the IC device 90 in the plan view. When the square SQ is detected and the size of the square SQ is the same as a threshold value stored in the memory 803 in advance, the test unit 16 itself may be determined as being correct and, when not, the test unit 16 itself may be determined as being not correct.

As described above, with the minimum number of points set by the setting part 804, whether or not the test unit 16 itself is correct may be quickly determined.

Note that, for example, the point P3-1 to point P3-4 maybe used for the determination as to whether or not the fixing state of the test unit 16 is good.

The number of points set in the upper surface 32 of the socket 3 exposed from the through hole 41 of the socket base 4 may be three or more.

Further, the number of points set in the bottom part 311 of the recess 31 of the socket 3 may be three or more.

### Third Embodiment

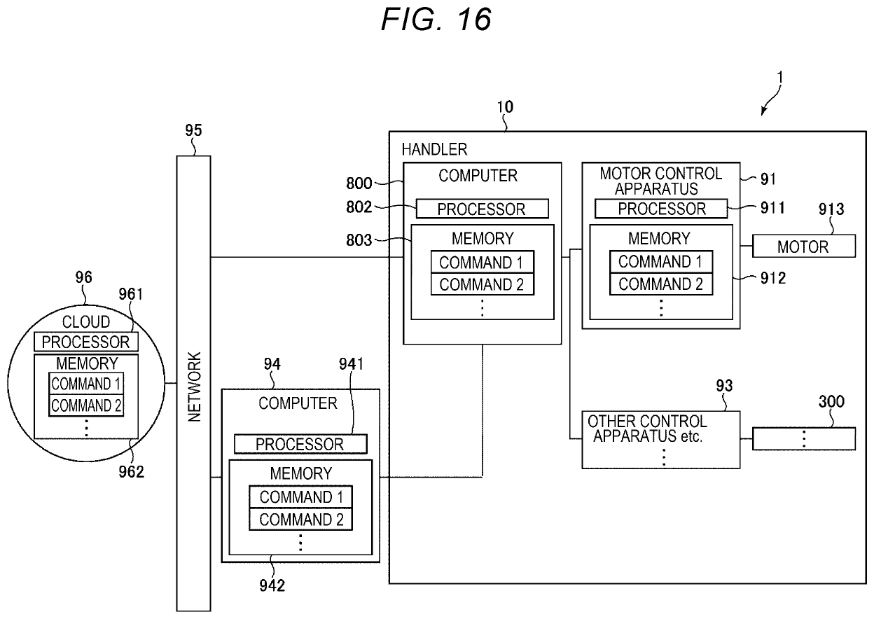

As below, the third embodiment of the electronic component handler and the electronic component tester of the present disclosure will be explained with reference to FIG. 16. The explanation will be made with a focus on the differences from the above described embodiments and the explanation of the same items will be omitted.

This embodiment is the same as the above described first embodiment except that the configuration of the electronic component tester is different.

As shown in FIG. 16, in the embodiment, the electronic component handler 10 as the handler contains a motor control apparatus 91 in addition to the control unit 800 formed by an industrial computer, and further contains another control apparatus 93.

The control unit 800 is coupled to the motor control apparatus 91 and the other control apparatus 93. In the control unit 800, the processor 802 may read commands from the memory 803 and execute control. Further, it is preferable that the control unit 800 is coupled to an I/F board coupled to the above described tester.

The motor control apparatus 91 has a processor 911 and a memory 912, and the processor 911 may read a command from the memory 912 and execute control. Further, the motor control apparatus 91 is coupled to a motor 913 and may control operation of the motor 913. Note that, for example, the motor 913 is a drive source that drives the tray transport mechanism 11A, the tray transport mechanism 11B, the device transport head 13, the device feed units 14, the tray transport mechanism 15, the device transport heads 17, the device collection units 18, the device transport head 20, the tray transport mechanisms 21, the tray transport mechanism 22A, or the tray transport mechanism 22B.

Note that the processor 802 of the control unit 800 may read a command from the memory 912 of the motor control apparatus 91 and execute control.

The other control apparatus 93 includes e.g. an apparatus that controls operation of the monitor 300 etc.

The above described respective control apparatuses may be separately provided from or integrally provided with a member to control. For example, the motor control apparatus 91 may be integrally provided with the motor 913.

The control unit 800 is connected to a computer 94 outside of the electronic component handler 10 as the handler. The computer 94 has a processor 941 and a memory 942. The processor 802 of the control unit 800 may read a command from the memory 942 and execute control.

The computer 94 is connected to a cloud 96 via a network 95 such as LAN. The cloud 96 has a processor 961 and a memory 962. The processor 802 of the control unit 800 may read a command from the memory 962 and execute control.

Note that the control unit 800 may be directly connected to the network 95.

### Fourth Embodiment

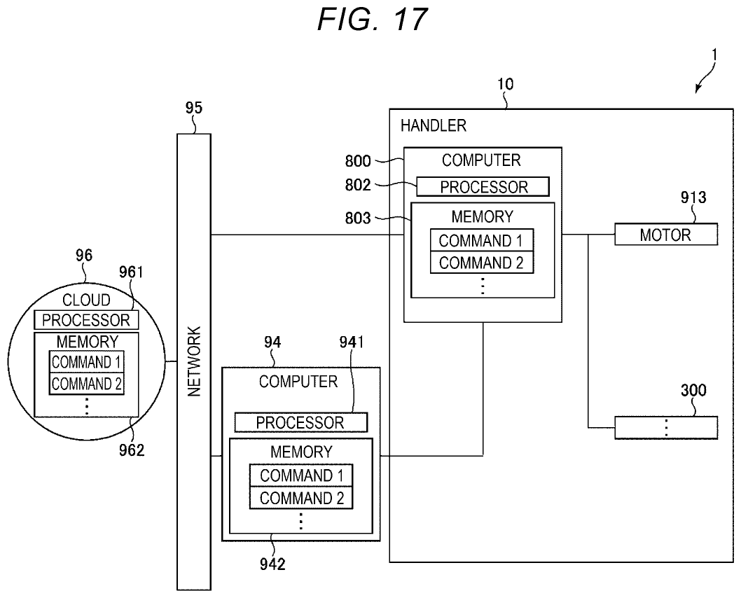

As below, the fourth embodiment of the electronic component handler and the electronic component tester of the present disclosure will be explained with reference to FIG. 17. The explanation will be made with a focus on the differences from the above described embodiments and the explanation of the same items will be omitted.

This embodiment is the same as the above described third embodiment except that the configuration of the electronic component tester is different.

In the embodiment shown in FIG. 17, the control unit 800 is configured to have a control function for the motor control apparatus 91 and a control function for the other control apparatus 93. That is, the control unit 800 has a configuration (integrally) containing the motor control apparatus 91 and the other control apparatus 93. The configuration contributes to downsizing of the control unit 800.

As above, the electronic component handler and the electronic component tester of the present disclosure are explained with respect to the illustrated embodiments, however, the present disclosure is not limited to those. The respective parts forming the electronic component handler and the electronic component tester may be replaced by arbitrary configurations that may fulfill the same functions. Further, arbitrary configurations may be added thereto.

Or, the electronic component handler and the electronic component tester of the present disclosure may be formed by a combination of arbitrary two or more configurations or features of the above described respective embodiments.

In the electronic component tester, detection as to whether or not the fixing state of the test unit is good and whether or not the test unit itself is correct is performed using the light radiation unit and the imaging unit in combination, however, the tester may make other detection. The other detection includes e.g. detection as to whether or not the IC device is present within the recess of the test unit, i.e., whether or not the IC device is left within the recess, detection as to whether or not two IC devices are placed one on top of the other within the recess of the test unit, etc.

What is claimed is:

1. An electronic component handler that transports an electronic component to a test unit testing electric characteristics of the electronic component and having a socket member provided with a recess in which the electronic component is placed, comprising:
a reference base having a reference surface in which the socket member is disposed;
a measuring unit that measures positions in a normal direction of the reference surface with respect to a plurality of points of the socket member;
a display unit; and
a control unit that displays position information based on the positions of the plurality of points on the display unit.

2. The electronic component handler according to claim 1, wherein
the socket member includes a socket having the recess and a socket base supporting the socket, and
the reference base has the reference surface to which the socket base is fixed and an opening part through which the electronic component passes when the electronic component is placed in the recess.

3. The electronic component handler according to claim 2, wherein
the measuring unit includes:
a light radiation unit being in a position fixed relative to the reference base and radiating light to the opening part; and
an imaging unit being in a position fixed relative to the reference base and capturing an image of the opening part radiated by the light.

4. The electronic component handler according to claim 1, wherein
the control unit determines appropriateness of a fixing state of the socket member based on the positions.

5. The electronic component handler according to claim 1, wherein
the measuring unit obtains the positions based on differences in number of pixels among the plurality of points in the image.

6. The electronic component handler according to claim 1, wherein
with an axis along a first line extending along the reference surface as a first axis, the measuring unit measures the plurality of points along the first axis.

7. The electronic component handler according to claim 6, wherein
with an axis extending along the reference surface along a second line crossing the first axis as a second axis, the measuring unit measures the plurality of points along the second axis.

8. The electronic component handler according to claim 2, wherein
the measuring unit measures positions in the normal direction of the reference surface with respect to the plurality of points within the opening part in a plan view from the normal direction of the reference surface, and
the light radiated to the opening part passes through the plurality of points.

9. The electronic component handler according to claim 3, wherein
the light radiation unit has a laser beam radiation part that radiates a laser beam as the light and a reflection part that reflects the laser beam.

10. The electronic component handler according to claim 9, wherein
the light radiation unit has a pivot supporting part that supports the reflection part to pivot the reflection part.

11. An electronic component tester that tests a transported electronic component, comprising:
a test unit testing electric characteristics of the electronic component and having a socket member provided with a recess in which the electronic component is placed;
a reference base having a reference surface in which the socket member is disposed;
a measuring unit that measures positions in a normal direction of the reference surface with respect to a plurality of points of the socket member;
a display unit; and
a control unit that displays position information based on the positions of the plurality of points on the display unit.

12. The electronic component tester according to claim 11, wherein
the socket member includes a socket having the recess and a socket base supporting the socket, and
the reference base has the reference surface to which the socket base is fixed and an opening part through which the electronic component passes when the electronic component is placed in the recess.

13. The electronic component tester according to claim 12, wherein
the measuring unit has:
a light radiation unit being in a position fixed relative to the reference base and radiating light to the opening part; and
an imaging unit being in a position fixed relative to the reference base and capturing an image of the opening part radiated by the light.

14. The electronic component tester according to claim 11, wherein
the control unit determines appropriateness of a fixing state of the socket member based on the positions.

15. The electronic component tester according to claim 11, wherein
the measuring unit obtains the positions based on differences in number of pixels among the plurality of points in the image.

16. The electronic component tester according to claim 11, wherein
with an axis along a first line extending along the reference surface as a first axis, the measuring unit measures the plurality of points along the first axis.

17. The electronic component tester according to claim 16, wherein
with an axis extending along the reference surface along a second line crossing the first axis as a second axis, the measuring unit measures the plurality of points along the second axis.

18. The electronic component tester according to claim 12, wherein
the measuring unit measures positions in the normal direction of the reference surface with respect to the plurality of points within the opening part in a plan view from the normal direction of the reference surface, and
the light radiated to the opening part passes through the plurality of points.

19. The electronic component tester according to claim 13, wherein
the light radiation unit has a laser beam radiation part that radiates a laser beam as the light and a reflection part that reflects the laser beam.

20. The electronic component tester according to claim 19, wherein
the light radiation unit has a pivot supporting part that supports the reflection part to pivot the reflection part.
